(19) United States
(12) Patent Application Publication
(10) Pub. No.: US 2014/0138721 A1
(43) Pub. Date: May 22, 2014

(54) LIGHT EMITTING DIODE HEAT-DISSIPATION CARRIER STRUCTURE

(71) Applicant: Hsu-Wen LIAO, Pingjhen City (TW)

(72) Inventor: Hsu-Wen LIAO, Pingjhen City (TW)

(21) Appl. No.: 13/679,564

(22) Filed: Nov. 16, 2012

(51) Int. Cl. H01L 33/64

(52) U.S. Cl. CPC H01L 33/64
USPC 257/89; 257/88

(57) ABSTRACT

An LED heat-dissipation carrier structure includes a circuit board having at least one LED chip mounted thereon; at least one electrical terminal pin having at an end connected to the LED chip on the circuit board and another end extended in a direction away from a rear side of the LED chip; a bowl-shaped metal-made heat-dissipation carrier for receiving the circuit board and the LED chip therein, and through a bottom of which the electrical terminal pin is extended away from the LED chip; and a light-pervious epoxy filled in the heat-dissipation carrier to completely cover the circuit board and the LED chip. With these arrangements, a watertight and dustproof LED with good heat dissipation ability is formed and suitable for mounting on outdoor signboards, signs or exterior walls of high-rise buildings.

### FIELD OF THE INVENTION

The present invention relates to a light emitting diode (LED) heat-dissipation carrier structure, and more particularly to a watertight and dustproof LED structure with excellent heat dissipation ability.

### BACKGROUND OF THE INVENTION

Light emitting diode (LED) has become a considerably mature technique now. Currently, one of the most important issues about LED is the dissipation of heat produced by the LED during operation thereof. Poor heat dissipation would cause rapid aging of LED chip to adversely affect the light emitting performance and service life of LED.

To apply LEDs to advertisement boards, signboards and large-size display screen on exterior wall of high-rise building, the inventor of the present invention not only designs a series of high-power LEDs, but also develops an LED heat-dissipation carrier structure for the high-power LEDs in an attempt to provide the LEDs with enhanced heat-dissipation ability.

### SUMMARY OF THE INVENTION

A primary object of the present invention is to provide a watertight and dustproof LED heat-dissipation carrier structure with excellent heat dissipation ability and suitable for using on outdoor signboards, signs or exterior walls of high-rise buildings.

To achieve the above and other objects, the LED heat-dissipation carrier structure according to the present invention includes a circuit board having at least one LED chip mounted thereon; at least one electrical terminal pin connected at an end to the LED chip on the circuit board and having another end extended in a direction away from a rear side of the LED chip; and a bowl-shaped metal-made heat-dissipation carrier for receiving the circuit board and the LED chip therein with the electrical terminal pin extending through a bottom thereof.

According to an embodiment of the present invention, the heat-dissipation carrier is provided on the bottom with at least one through hole corresponding to the electrical terminal pin, so that the electrical terminal pin can extend through the heat-dissipation carrier via the through hole in the direction away from the rear side of the LED chip. Further, a part of the outer surface of the electrical terminal pin corresponding to the heat-dissipation carrier is coated with an insulating paint or an insulating adhesive, or is provided with an insulating sleeve to provide insulation between the electrical terminal pin and the bottom of the heat-dissipation carrier.

According to another embodiment of the present invention, the through hole provided on the bottom of the heat-dissipation carrier has a T-shaped hollow insulating sleeve fitted therein, so that the electrical terminal pin is extended through the hollow insulating sleeve to isolate from the bottom of the heat-dissipation carrier.

According to a further embodiment of the present invention, the heat-dissipation carrier has an insulating layer electrically plated on its outer surface.

According to a further embodiment of the present invention, the circuit board is provided with at least one connection hole corresponding to the at least one electrical terminal pin, and an end of the electrical terminal pin is extended into the connection hole to connect with the LED chip. Further, the circuit board is provided with conducting wires for electrically connecting to the LED chip and the electrical terminal pin.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of an LED heat-dissipation carrier structure according to a first preferred embodiment of the present invention;

FIG. 2 is an exploded view of FIG. 1;

FIG. 3 is an sectional view of FIG. 1; and

FIG. 4 is a partially exploded perspective view of an LED heat-dissipation carrier structure according to another embodiment of the present invention.

### DETAILED DESCRIPTION OF THE PREFERRED EMBODIMENTS

The present invention will now be described with some preferred embodiments thereof and with reference to the accompanying drawings. For the purpose of easy to understand, elements that are the same in the preferred embodiments are denoted by the same reference numerals.

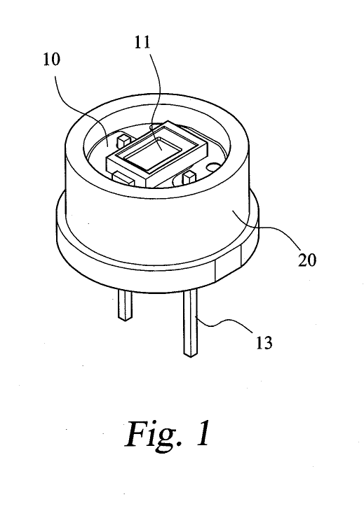

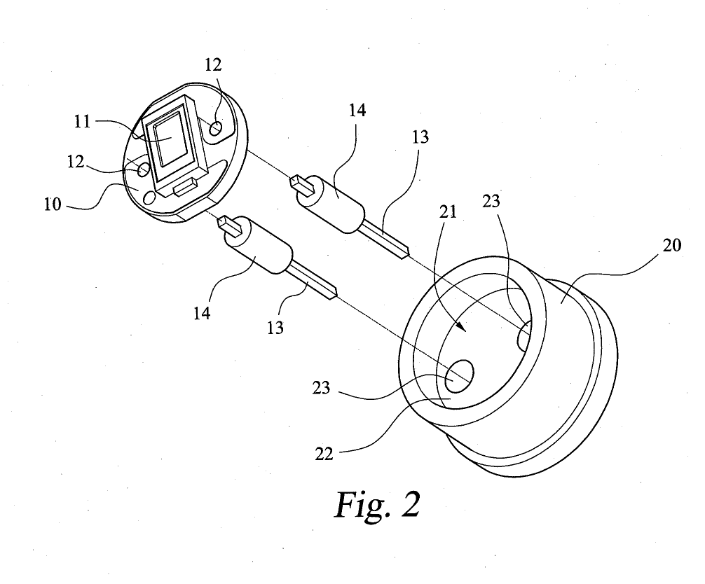

Please refer to FIGS. 1 and 2 that are assembled and exploded perspective views, respectively, of a light emitting diode (LED) heat-dissipation carrier structure according to a first preferred embodiment of the present invention. As shown, the LED heat-dissipation carrier structure of the present invention includes a circuit board 10, at least one LED chip 11 mounted on the circuit board 10, at least one connection hole 12 provided on the circuit board 10, at least one electrical terminal pin 13 extended through the at least one connection hole 12 in a direction away from a rear side of the LED chip 11, and a heat-dissipation carrier 20. In practical implementation of the present invention, there may be provided a plurality of LED chips 11 emitting the same light color or a plurality of LED chips emitting different light colors. The circuit board 10 can be a metal substrate with good heat dissipation ability, such as an aluminum substrate; or a composite substrate made of a metal and a non-metal material.

In the embodiment illustrated in FIGS. 1 and 2, there are provided two electrical terminal pins 13, and the circuit board 11 is provided with two connection holes 12 corresponding to the two electrical terminal pins 13, allowing the electrical terminal pins 13 to extend respective one end through the connection holes 12 and be soldered to the circuit board 10. The circuit board 10 further has conducting wires (not shown) provided thereon for electrically connecting to between the LED chip 11 and the electrical terminal pins 13. Another ends of the electrical terminal pins 13 can be electrically connected to an external circuit board or a power supply to form a circuit loop between the circuit board 10 and the external circuit board or power supply for supplying electric power needed by the LED chip 11 to emit light. According to the present invention, there can be only one electrical terminal pin 13, and the heat-dissipation carrier 20 with a conducting metal characteristic can be utilized to form a circuit loop, too. Alternatively, the present invention can be provided with more than two electrical terminal pins 13 separately electrically connected to multiple LED chips 11 that emit different light colors.

The heat-dissipation carrier 20 is shaped like a bowl having an open top. The heat-dissipation carrier 20 is integrally formed of a metal material, such as an aluminum material with good heat dissipation ability. The heat-dissipation carrier 20 can have a round cross sectional shape; or a polygonal cross sectional shape, such as a square, a rectangular, a triangular, a hexagonal or an octagonal shape; or an irregular cross sectional shape, such as a trapezoidal or a rhombic shape.

The heat-dissipation carrier 20 internally defines a receiving space 21 for accommodating the circuit board 10 and the LED chip 11 therein. The LED chip 11 is positioned in the receiving space 21 with a light-emitting side facing toward the open top of the bowl. A bottom 22 of the heat-dissipation carrier 20 opposite to the open top is formed with through holes 23 corresponding to the electrical terminal pins 13, so that the electrical terminal pins 13 can extend through the through holes 23 on the bottom 22 of the heat-dissipation carrier 20 in the direction away from the rear side of the LED chip 11.

Since the heat-dissipation carrier 20 is made of a metal material, it is necessary to prevent short circuit due to contact of the electrical terminal pins 13 with the heat-dissipation carrier 20. For this purpose, a part of the outer surface of every electrical terminal pin 13 corresponding to the heat-dissipation carrier 20 is coated with an insulating paint or an insulating adhesive or is provided with an insulating sleeve 14. Thus, the electrical terminal pins 13 extended through the through holes 23 on the bottom 22 of the heat-dissipation carrier 20 are electrically insulated from the bottom 22 by the insulating paint, the insulating adhesive or the insulating sleeves 14. Of course, it is also possible to electrically plate an insulating layer on the surface of the heat-dissipation carrier 20 to achieve the same insulating effect.

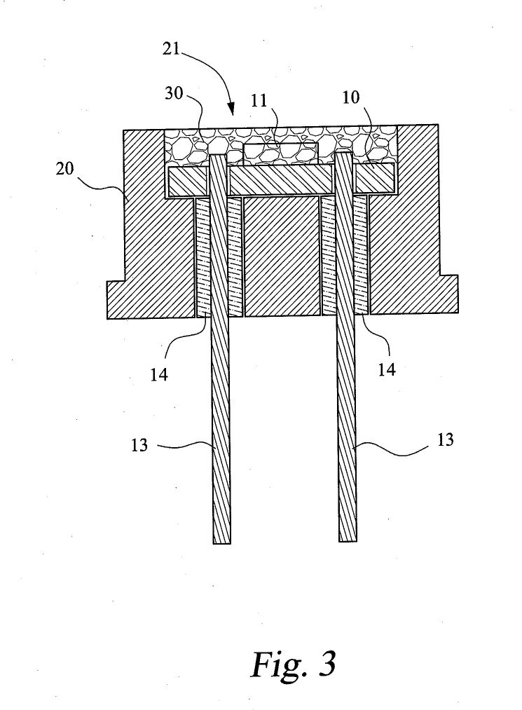

FIG. 3 is a sectional view of FIG. 1. As can be seen in FIG. 3, the insulating sleeves 14 can be first fitted on the electrical terminal pins 13 before the latter are extended through the through holes 23. Alternatively, the hollow insulating sleeves 14 can be first fitted in the through holes 23 and the electrical terminal pins 13 are then extended through the insulating sleeves 14. The insulating sleeves 14, in addition to providing insulation between the electrical terminal pins 13 and the heat-dissipation carrier 20, also provides a watertight seal between the electrical terminal pins 13 and the through holes 23 on the bottom 22 of the heat-dissipation carrier 20. When the circuit board 10 and the LED chip 11 have been mounted in the receiving space 21 of the heat-dissipation carrier 20, the open top of the heat-dissipation carrier 20 can be sealed by filling a light-pervious epoxy 30 in the receiving space 21 and allowing the epoxy 30 to set, so that the circuit board 10 and the LED chip 11 in the heat-dissipation carrier 20 are isolated from external environment to complete a watertight and dustproof high-power LED with excellent heat dissipation ability.

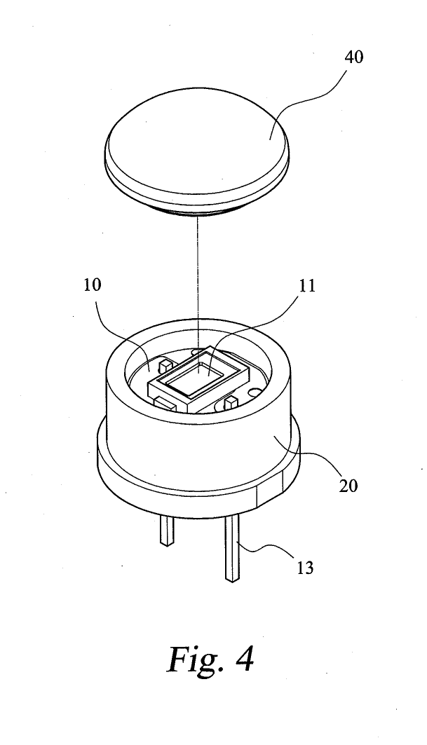

FIG. 4 is a partially exploded perspective view of a second embodiment of the present invention. In the second embodiment, a light-pervious cap 40 is further provided for connecting to the open top of the heat-dissipation carrier 20, so that the latter is sealed to complete a watertight and dustproof high-power LED with excellent heat dissipation ability.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A light emitting diode (LED) heat-dissipation carrier structure, comprising:
a circuit board having at least one LED chip mounted thereon;
at least one electrical terminal pin having an end connected to the LED chip on the circuit board, and another end extended in a direction away from a rear side of the LED chip; and
a heat-dissipation carrier being made of a metal material and shaped as a bowl having an open top and a bottom for receiving the circuit board and the LED chip therein; and the bottom being provided with at least one through hole corresponding to the electrical terminal pin, so that the electrical terminal pin can be extended through the bottom via the through hole.

2. The LED heat-dissipation carrier structure as claimed in claim 1, wherein the circuit board is selected from the group consisting of a metal substrate and a composite substrate formed of a metal and a non-metal material.

3. The LED heat-dissipation carrier structure as claimed in claim 2, wherein the circuit board is an aluminum substrate.

4. The LED heat-dissipation carrier structure as claimed in claim 1, wherein there is a plurality of LED chips mounted on the circuit board to emit the same light color or to emit different light colors.

5. The LED heat-dissipation carrier structure as claimed in claim 1, wherein a part of the electrical terminal pin corresponding to the heat-dissipation carrier is coated with an insulating paint or an insulating adhesive, or is provided with an insulating sleeve, so that the electrical terminal pin is electrically insulated from the bottom of the heat-dissipation carrier.

6. The LED heat-dissipation carrier structure as claimed in claim 1, wherein the through hole on the bottom of the heat-dissipation carrier is internally fitted with a hollow insulating sleeve, and the electrical terminal pin being extended through the insulating sleeve to be electrically insulated from the bottom of the heat-dissipation carrier.

7. The LED heat-dissipation carrier structure as claimed in claim 1, wherein the heat-dissipation carrier is configured to have a cross-sectional shape selected from the group consisting of a round shape, a square shape, a rectangular shape, a polygonal shape, and an irregular shape.

8. The LED heat-dissipation carrier structure as claimed in claim 1, wherein the metal material for making the heat-dissipation carrier is an aluminum material.

9. The LED heat-dissipation carrier structure as claimed in claim 1, wherein the heat-dissipation carrier has an insulating layer electrically plated on its outer surface.

10. The LED heat-dissipation carrier structure as claimed in claim 1, wherein the circuit board is provided with at least one connection hole, to which the at least one electrical terminal pin is connected; and wherein the circuit board is provided with conducting wires for electrically connecting to the at least one LED chip and the at least one electrical terminal pin.

11. The LED heat-dissipation carrier structure as claimed in claim 1, further comprising a light-pervious epoxy filled in the heat-dissipation carrier to completely cover the circuit board and the LED chip.

12. The LED heat-dissipation carrier structure as claimed in claim 1, further comprising a light-pervious cap connected to the open top of the heat-dissipation carrier to seal the latter.
